(19) United States
(12) Patent Application Publication
(10) Pub. No.: US 2004/0046247 A1
(43) Pub. Date: Mar. 11, 2004

(54) Hermetic semiconductor package

(75) Inventor: Steven A. Tower, New Bedford, MA (US)

Correspondence Address: WIGGIN & DANA LLP, ATTENTION: PATENT DOCKETING, ONE CENTURY TOWER, P.O. BOX 1832, NEW HAVEN, CT, 06508-1832, US

(73) Assignee: Olin Corporation, a corporation of the Commonwealth of Virginia

(21) Appl. No.: 10/653,764

(22) Filed: Sep. 3, 2003

Related U.S. Application Data
(60) Provisional application No. 60/409,179, filed on Sep. 9, 2002.

(51) Int. Cl. H01L 23/043

(52) U.S. Cl. 257/708; 257/699; 257/659; 257/729

(57) ABSTRACT

A package for encasing one or more semiconductor devices includes a composite base component with opposing first and second surfaces formed from a mixture of metallic powders. A first metallic powder is copper or a copper-base alloy and a second metallic powders is a metal or metal alloy with a coefficient of thermal expansion less than that of copper. There is sufficient copper or copper-base alloy present for the composite base to preferably have a coefficient of thermal expansion of at least 9×10⁻⁶/° C. A ring frame formed from a nickel/iron-based alloy having a plurality of interconnections extending through sidewalls thereof is bonded to the composite base by a braze with a melting temperature in excess of 700° C. In an alternative embodiment, the composite base brazed to a frame formed from a ceramic having a coefficient of thermal expansion in excess of 8×10⁻⁶/° C.

### CROSS REFERENCE TO RELATED APPLICATION(S)

This patent application claims priority to U.S. provisional patent application serial No. 60/409,179 that was filed on Sep. 9, 2002. The subject matter of that provisional patent application is incorporated by reference in its entirety herein.

### U.S. GOVERNMENT RIGHTS

Not Applicable

### BACKGROUND OF THE INVENTION

1. Field of the Invention

This invention relates to hermetic semiconductor packages, such as hybrid packages. More particularly, this invention relates to composite bases for hermetic semiconductor packages. The bases have a controlled coefficient of thermal expansion that reduces linear distortion of the package during assembly and operation. Reduced linear distortion improves the alignment between conductors, such as optical fibers and lead frames, and encased integrated circuit devices.

2. Description of the Related Art

Semiconductor packages provide mechanical and environmental protection to one or more integrated circuit semiconductor devices. In addition, the semiconductor packages provide a mechanism to transmit information from within the packages to outside the packages. A hybrid semiconductor package typically includes circuitry within the package electrically interconnecting a plurality of integrated circuit devices. Information is typically transmitted between the encased semiconductor devices by electrical signals transmitted by bond wires and internal metalized circuitry. Communication with the outside environment is typically by electrical signals via lead frames or by opto-electronic signals via optical fibers.

Most integrated circuit devices are formed from either silicon or gallium arsenide. These materials have relatively low coefficients of thermal expansion. Therefore, the package components are typically also formed from materials having a relatively low coefficient of thermal expansion (C.T.E.). For example, U.S. Pat. No. 4,172,261 Tsuzuki, et al discloses a package base formed from either Kovar (a low expansion metal alloy having a nominal composition of, by weight, 29% nickel, 17% cobalt, and 54% iron) or from molybdenum. U.S. Pat. No. 4,172,261 is incorporated by reference in its entirely herein.

While both Kovar and molybdenum have relatively low coefficients of thermal expansion, the materials have relatively poor thermal conductivity. As electrical signals are transmitted through the integrated circuit devices, a portion of the electrical power is transformed to heat due to an internal resistance. As an increase in the operating temperature of an integrated circuit devices reduces the operating life, it is desirable to remove the heat from the integrated circuit device. To that end, composite materials having controlled coefficients of thermal expansion and thermal conductivities higher than Kovar and molybdenum have been disclosed as package bases for semiconductor packages.

Commonly owned U.S. Pat. No. 5,111,277 to Medieros, III et al and U.S. Pat. No. 5,886,407 to Polese, et al, disclose bases formed by combining metal powders having different coefficients of thermal expansion. Typically, a high expansion, high thermal conductivity material, such as copper is combined with at least one lower coefficient of thermal expansion material, such as tungsten. As described in more detail below, the composite base is typically bonded to a Kovar ring frame and the base is tailored to have a coefficient of thermal expansion similar to that of Kovar. The U.S. Pat. No. 5,111,277 patent discloses a mixture of tungsten and copper with from about 5% to 25%, by weight, of copper and preferably about 15%, by weight, of copper. Likewise, U.S. Pat. No. 5,886,407 discloses tungsten to copper ratios of between about 80/20 and 90/10, by weight, with a preferred ratio of 85/15, by weight. Both U.S. Pat. No. 5,111,277 and U.S. Pat. No. 5,886,407 are incorporated by reference in their entireties herein.

Typically, the base component is bonded to the ring frame by a relatively low melting temperature gold-base solder, for example the gold/tin eutectic (by weight, 80% gold and 20% tin with a melting temperature of 276° C.). Prior to soldering, both the base component and the ring frame are coated with a layer of nickel followed by a layer of gold. As described herein below, it is increasingly critical that the location of the integrated circuit devices and of the fiber optic tubes and/or lead frames be accurately and reproducibly located with relation to one another. A typical alignment requirement for optical components is +/−0.001 inch per inch, or better. While such accuracy is achievable with gold/tin eutectic soldered package assemblies, the high volume of gold required dramatically increases the cost of the hybrid package.

There remains a need in the art for a hermetic semiconductor package capable of satisfying the alignment requirements for optical components that does not require significant amounts of expensive materials such as gold.

### BRIEF SUMMARY OF THE INVENTION

In accordance with the invention, there is provided a package for encasing one or more semiconductor devices. The package has a composite base component with opposing first and second surfaces formed from a mixture of metallic powders. A first metallic powder is copper or a copper-base alloy and a second metallic powder is a metal or metal alloy with a coefficient of thermal expansion less than that of copper. There is sufficient copper or copper-base alloy present for the composite base to have a coefficient of thermal expansion of at least 9×10⁻⁶/° C. A ring frame formed from a nickel/iron-based alloy having a plurality of interconnections extending through sidewalls thereof is bonded to the composite base by a braze with a melting temperature in excess of 700° C.

In one aspect of the invention, the composite base is a mixture of copper and tungsten with from 28% to 38%, by weight, of copper and the braze is an alloy of silver and copper with from 20% to 40%, by weight, of copper. The ring frame is preferably Kovar.

One feature of the invention is that optical packages utilize lasers to generate light signals creating significant heat and the copper tungsten composite of the invention provides significant advantages over the prior art including much better thermal conductivity while maintaining heat sink flatness without gold solders or expensive post brazing flattening (machining) operations. The higher copper content tungsten copper composite is easier to make, easier to plate, easier to machine, lighter and less brittle than lower copper content composites.

In a second aspect of the invention, the composite base is supported by a ceramic frame that is a mixture of a lower coefficient of thermal expansion ceramic and a higher coefficient of thermal expansion glass. Preferably, there is from 92% to 96% of a ceramic such as alumina and the balance is a glass such as a barium containing silicate.

The details of one or more embodiments of the invention are set forth in the accompanying drawings and the description below. Other features, objects and advantages of the invention will be apparent from the description and drawings, and from the claims.

### BRIEF DESCRIPTION OF THE DRAWINGS

FIG. 1 illustrates a hybrid semiconductor package in accordance with the invention in cross-sectional view.

FIG. 2 is the hybrid semiconductor package of claim 1 in top planar view.

FIG. 3 graphically illustrates the relationship between weight percent of copper and the coefficient of thermal expansion of a copper/tungsten composite base component.

FIG. 4 graphically illustrates the coefficient of thermal expansion of Kovar as a function of temperature.

FIG. 5 illustrates in bottom planar view a ceramic frame for received a composite base of the invention.

FIG. 6 illustrates in cross-sectional representation the a composite base of the invention bonded to the ceramic frame of FIG. 5.

Like reference numbers and designations in the various drawings indicated like elements.

### DETAILED DESCRIPTION

Throughout this patent application, all percents are weight percent unless otherwise noted. The word “base” or “bases” when appended to an alloy composition (such as goldbase) indicates that the alloy contains at least 50% by weight of the base element.

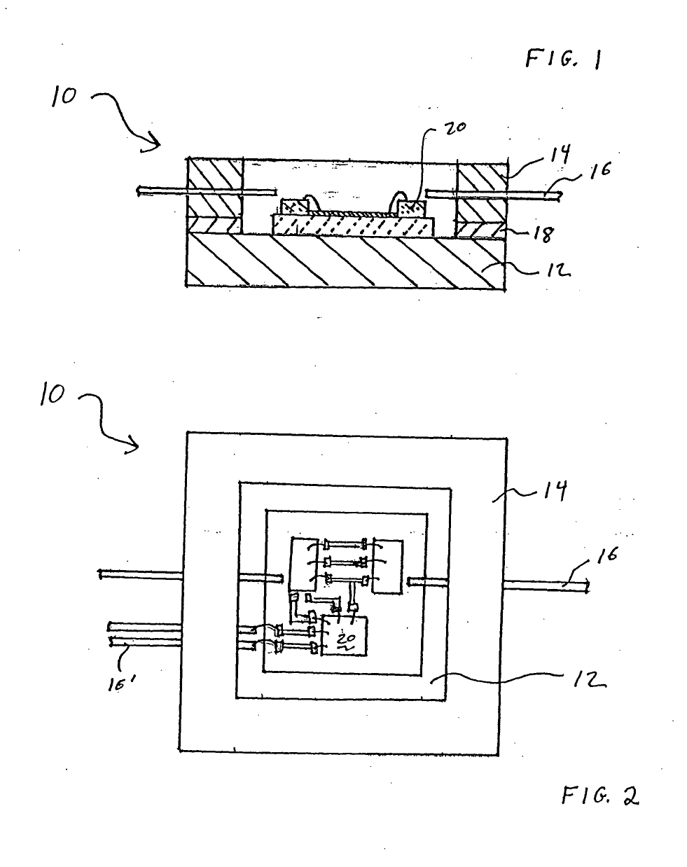

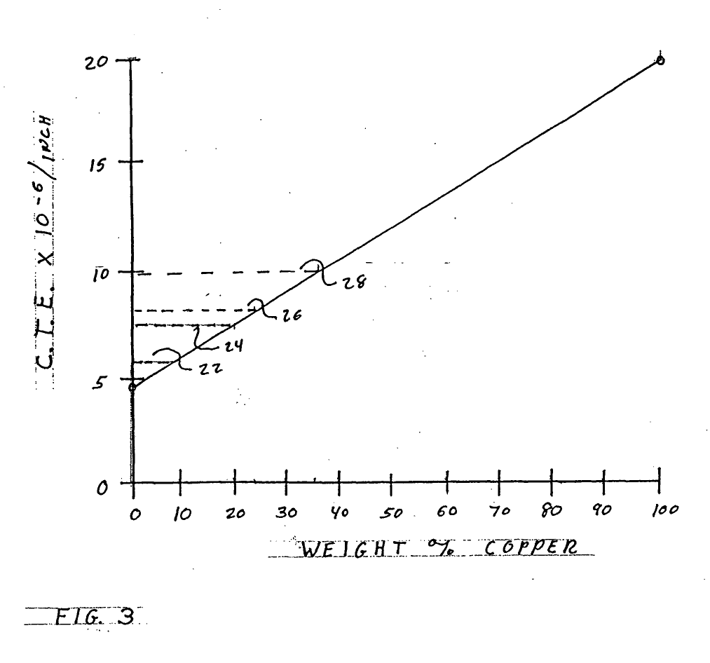

FIGS. 1 and 2 illustrate a hermetic semiconductor package 10 with improved dimensional control and heat dissipation in accordance with the present invention. While the package illustrated in FIGS. 1 and 2 is a hybrid package, other semiconductor packages of similar construction would also benefit from the present invention.

The hermetic hybrid electronic package 10 is assembled from a plurality of discrete components that are joined by brazing and/or welding and are used to house opto-electronic and/or electronic sub-assemblies. The components include a base 12, a ring frame 14, a lid (not shown), and interconnections 16, 16′ that are bonded to, and electrically isolated from, the ring frame by glass-metal seals and/or multi-layer ceramic feed throughs. The interconnections may be an opto-electronic coupling 16, such as an optical fiber, or an electrical coupling 16′, such as a lead frame. While in the prior art it was usual to assemble these components using gold-based brazing alloys and gold plated components, the present invention is drawn to the use of lower cost components that provide improved dimensional stability and higher heat dissipation; both characteristics that are of increasing importance for the housing of opto-electrical devices, LED light sources, and other semi-conducting units.

More particularly, the base 12 is hermetically attached to the ring frame 14 by a braze 18 that has a melting temperature in excess of 700° C. The maximum melting temperature of the braze is less than the melting temperature of the composite base or a discrete component of the composite base. A preferred braze material is an alloy containing silver and copper. More preferably, the braze consists essentially of, by weight, from 20% to 40% copper and the balance is silver and inevitable impurities. Most preferably, the braze consists essentially of from 26% to 30%, by weight, copper and the balance is silver and inevitable impurities and nominally, the copper-silver eutectic of 28.1 wt. % copper, balance silver, that melts at 779.1° C.

The base 12 is made from a composite metal, such as copper-tungsten or copper-molybdenum with a copper content effective to provide the base with a coefficient of thermal expansion of at least 9×10⁻⁶/° C. For a copper-tungsten composite, a preferred copper content is, by weight, from 24% to 38%, and more preferably of from 29% to about 35%. With reference to FIG. 3, the coefficient of thermal expansion of a composite material generally follows a rule of mixtures and is proportional to the amount of each constituent. As such, an approximately linear relationship as shown is FIG. 3 is achieved extending from a C.T.E. of 4.6×10⁻⁶/° C. for 100% tungsten to 19.95×10⁻⁶/° C. for 100% copper. This comports to a C.T.E. of between about 6×10⁻⁶/° C. (reference line 22) and about 7.5×10⁻⁶/° C. for the prior art composite materials. The composite bases of the invention have a C.T.E. of between about 8×10⁻⁶/° C., at 24%, by weight, copper (reference numeral 26) and 10×10⁻⁶/° C., at 35% by weight copper (reference numeral 28). Preferably, the C.T.E. is in excess of 9×10⁻⁶/C.

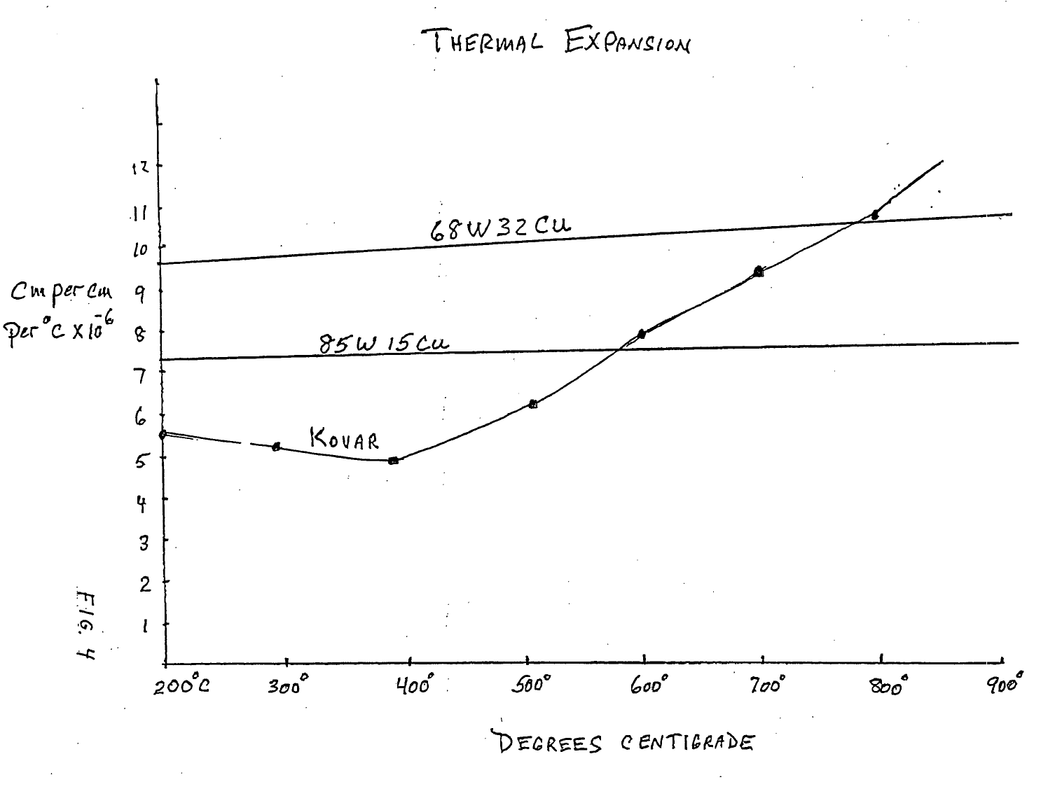

An advantage of the higher C.T.E. range of the composites of the invention is seen from the C.T.E. values of Kovar as a function of temperature illustrated in FIG. 4. The C.T.E.'s of the composite and of the Kovar base approximately match at the Cu/Ag brazing temperature.

Optionally, the base incorporates metal composite and ceramic portions. In all cases, the material components (base and ring frame) exhibit similar thermal expansion/contraction characteristics to minimize the residual stress and distortion of the assembled components. A typical brazing alloy is 72% copper-28% silver that melts at 780° C. and requires exposure of the package components to approximately 800° C. to accomplish assembly by brazing.

Copper-tungsten and copper-molybdenum composites are preferred for the base 12 components of hybrid packages 10. When using copper-silver alloys as braze 18, we have found that copper tungsten consisting essentially of, by weight, 24% to 38% copper with the balance tungsten is preferred, and from 29% to 35% copper, is most preferred. Using these preferred compositions the composite bases expand and contract at a similar rate to the other package components such as a Kovar ring frame 14. Closely matching thermal expansion/contraction minimizes dimensional distortion of the base component, thus eliminating the need for subsequent secondary operations such as machining, grinding, etc. The assembled packages are often mounted on heat sinks and the enhanced flatness of their outside surfaces, which contact the heat sink, serves to increase the efficiency of heat transfer across the interface. The higher copper content also increases the thermal conductivity of the composite; this facilitates the removal of heat that may be generated by the opto-electronic or electronic sub-assemblies, mounted on the base components.

The base component 12 typically becomes the mounting platform for opto-electronic or electronic devices 20. It is becoming increasingly critical that such devices are accurately and reproducibly located with relation to other components of the package assembly, specifically the optical interconnect components 16. The alignment requirement for optical components is presently ±0.001 inch per inch or better. The use of copper-silver brazing alloys coupled with higher copper content CuW composites provides packages that meet these requirements with improved reliability and thermal performance while using lower cost materials that can be assembled with a higher yielding /lower cost process.

Some package designs employ bases with both ceramic and metal portions. One example is a full section ceramic with apertures or cut-outs spanned by metal or composite metal portions, as disclosed in U.S. Pat. No. 5,111,277. Such metallic portions would be used as sub-mounts for the active heat dissipating devices or circuits. With such devices it is desirable for the ceramic and metallic components to have similar thermal expansion characteristics. Ceramic options include any insulating material with a C.T.E. over 8×10⁻⁶/° C. and can be alumina-based with high expansion glasses added or other commercially available ceramics like magnesia partially stabilized zirconium (Carpenter Technology, Reading, Pa.) or Forsterite, a magnesium silicate.

Typically ceramics contain 92-96% alumina and 4-8% glass; the glass phase, typically borosilicates, is desirable for ease of processing but it generally reduces the thermal expansion coefficient rendering the mixtures to have a lower CTE than the composite metal portions. Thus a preferred ceramic material to be used in conjunction the preferred W-30% Cu metallic components would consist essentially of, by weight, 92-96% alumina and 4-8% of a high CTE glass, such as barium containing silicates. Alternatives for the alumina component include zirconia and aluminum nitride ceramics.

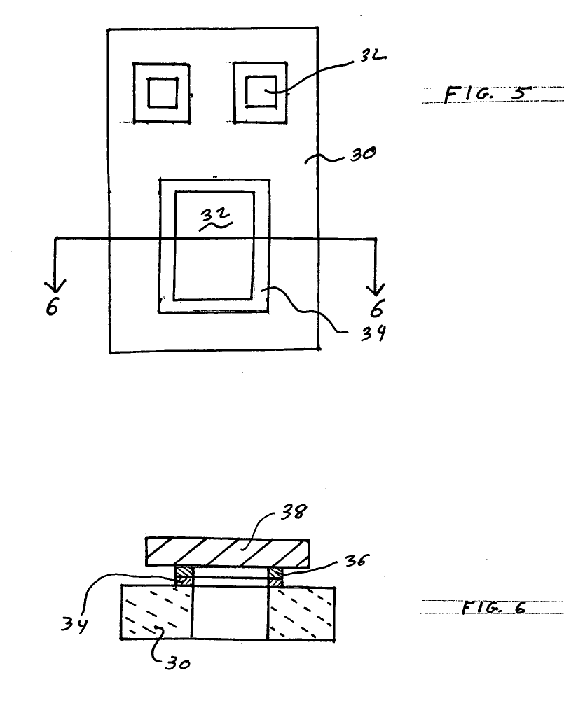

FIG. 5 illustrates a ceramic frame 30 having a plurality of cut-outs 32. Circumscribing the cut-outs 32 is a metallization layer 34 that may be a fired tungsten paste. With reference to FIG. 6, a braze 36 is positioned on the metallization layer 34 and composite base 38 is positioned on an opposing side of the braze 36. The assembly is made hermetic by heating to the brazing temperature to bond the composite base 38 to the ceramic frame 30.

The present invention is better understood with reference to the Examples that follow.

### EXAMPLES

### Example 1

A 14-lead “butterfly package”, the standard for housing laser diode components, was assembled using a W-18%, by weight, Cu base, a Kovar ring frame and CuAg braze. The linear distortion of the base was found to be ±0.005 inch per inch; the thermal conductivity was 180W/mK. With a gold-tin solder, the distortion was ±0.002 inch per inch.

### Example 2

A 14-lead butterfly package was made using W-30%, by weight, Cu and CuAg braze; the distortion was ±0.0005 inch per inch; the thermal conductivity was 235W/mK. A similar package using W-32%, by weight, Cu distorted ±0.0002 inch per inch; the thermal conductivity was 235W/mK.

One or more embodiments of the present invention have been described. Nevertheless, it will be understood that various modifications may be made without departing from the spirit and scope of the invention. Accordingly, other embodiments are within the scope of the following claims.

What is claimed is:

1. A package for encasing one or more semiconductor devices, comprising:
a composite base component with opposing first and second surfaces formed from a mixture of metallic powders, wherein a first of said metallic powders is copper or a copperbase alloy and a second of said metallic powders is a metal or metal alloy with a coefficient of thermal expansion less than that of copper, said copper or copper-base alloy being present in an amount effective for said composite base to have a coefficient of thermal expansion of at least 8×10⁻⁶/° C.;
a ring frame formed from a nickel/iron-based alloy having a plurality of interconnections extending through sidewalls thereof;
and a braze with a melting temperature in excess of 700° C. bonding said seal ring to said first surface of said composite base.

2. The package of claim 1 wherein said second of said metallic powders is selected from the group consisting of tungsten, molybdenum, mixtures thereof and alloys thereof.

3. The package of claim 2 wherein said second metal is tungsten and said copper or copper base alloy is present in an amount of from 24% to 38%, by weight.

4. The package of claim 3 wherein said copper or copper base alloy is present in an amount of from 29% to 35%, by weight.

5. The package of claim 3 wherein said ring frame is formed from Kovar.

6. The package of claim 5 wherein said braze is an alloy of silver and copper containing from 20% to 40%, by weight, of copper.

7. The package of claim 6 wherein said braze contains from 26% to 30%, by weight, of copper.

8. The package of claim 7 wherein said braze has a nominal composition of said silver/copper eutectic.

9. The package of claim 7 wherein said plurality of interconnections includes at least one optical fiber.

10. The package of claim 9 wherein said plurality of interconnections includes at least one lead frame lead.

11. The package of claim 9 wherein said one or more semiconductor devices are supported by a hybrid circuit.

12. The package of claim 11 having a linear distortion of less than 0.001 inch per inch following assembly.

13. An assembly for a semiconductor package comprising:
a frame formed from a ceramic having a coefficient of thermal expansion in excess of 8×10⁻⁶/° C., said frame having at least one aperture extending therethrough;
a metallization layer circumscribing said at least one aperture;
a composite base with opposing first and second surfaces formed from a mixture of metallic powders, wherein a first of said metallic powders is copper or a copper-base alloy and a second of said metallic powders is a metal or metal alloy with a coefficient of thermal expansion less than that of copper, said copper or copper-base alloy being present in an amount effective for said composite base to have a coefficient of thermal expansion of at least 8×10⁻⁶/° C.; and
a braze having a melting temperature in excess of 700° C. bonding said composite base to said frame.

14. The package of claim 13 wherein said ceramic is a mixture of a low coefficient of thermal expansion ceramic and a higher coefficient of thermal expansion glass.

15. The package of claim 14 wherein said ceramic is selected from the group consisting of alumina, zirconia and aluminum nitride and present in an amount of from about 92% to 96%, by weight.

16. The package of claim 15 wherein said higher coefficient of thermal expansion is a barium containing silicate glass.

17. The package of claim 16 wherein said ceramic is alumina.

18. The package of claim 17 wherein said braze is an alloy of silver and copper containing from 20% to 40%, by weight, of copper.

19. The package of claim 18 wherein said braze contains from 26% to 30%, by weight, of copper.

20. The package of claim 18 wherein said second of said metallic powders is selected from the group consisting of tungsten, molybdenum, mixtures thereof and alloys thereof.

21. The package of claim 20 wherein said second metal is tungsten and said copper or copper base alloy is present in an amount of from 24% to 38%, by weight.

22. The package of claim 21 wherein said copper or copper base alloy is present in an amount of from 29% to 35%, by weight.
